(19) United States
(12) Patent Application Publication
(10) Pub. No.: US 2005/0104129 A1
(43) Pub. Date: May 19, 2005

(54) Semiconductor programmable device

(76) Inventors: Jui-Lung Chen, Hsinchu (TW); Yang-Chen Hsu, Hsinchu City (TW); Chien-Jiun Wang, Yonghe City (TW)

Correspondence Address: J.C. Patents, Inc., 4 Venture, Suite 250, Irvine, CA, 92618, US

(21) Appl. No.: 10/817,777

(22) Filed: Apr. 2, 2004

(30) Foreign Application Priority Data
Nov. 14, 2003 (TW) 92131930

(51) Int. Cl. H01L 29/76; H01L 31/062; H01L 29/94

(52) U.S. Cl. 257/365; 257/379; 257/296; 257/300

(57) ABSTRACT

A semiconductor programmable device is provided. The semiconductor programmable device comprises a P-type substrate, an N-well, an NMOS capacitor and a PMOS transistor. The N-well is formed in the P-type substrate. The NMOS capacitor is configured on the P-type substrate. The PMOS transistor is configured on the N-well. A source/drain of the PMOS transistor is electrically connected to a gate of the NMOS capacitor. A control voltage is applied to a gate of the PMOS transistor. A programming voltage is applied to the source/drain of the PMOS transistor. The programming voltage is large enough to cause a breakdown of a gate oxide layer of the NMOS capacitor. The gate oxide layer of the NMOS capacitor has a thickness identical to the gate oxide layer of the PMOS transistor.

### CROSS-REFERENCE TO RELATED APPLICATION

This application claims the priority benefit of Taiwan application serial no. 92131930, filed on Nov. 14, 2003.

### BACKGROUND OF THE INVENTION

1. Field of the Invention

The present invention relates to a method of fabricating a semiconductor device. More particularly, the present invention relates to a method of fabricating a semiconductor programmable device.

2. Description of the Related Art

Most semiconductor products are fabricated after conducting a series of complicated processes. Typically, the parameters and operating environment of each process will affect the yield of the product. Thus, the most important issue facing the semiconductor industry is to develop ways for increasing overall yield of the product.

To prevent any significant drop in the quantity of semiconductor chips produced leading to a low product yield, a number of backup devices for repairing any defective devices is often fabricated on the chip besides the required devices. Furthermore, the chip also has safety fuses thereon for controlling the connection with the backup devices as well as the number of backup devices to be used.

In the earlier type of backup systems, defective devices are often replaced by the backup devices. The connections with the backup devices are achieved by severing a safety fuse using a laser beam. For a chip using this repair technique, repair is no longer possible after the chip has been packaged. Yet, a packaged chip may not be defect free. In recent years, another chip repair method has been developed. Instead of a conventional fuse, a semiconductor device serves as the fuse. The semiconductor device is a metallic-oxide semiconductor (MOS) capacitor and connection with the MOS capacitor is controlled by another semiconductor device, namely, a MOS transistor.

FIG. 1A is a schematic cross-sectional view of a conventional semiconductor programmable device. As shown in FIG. 1, an NMOS transistor 102 and an NMOS capacitor 104 are formed on a P-type substrate 100. The NMOS transistor 102 has a gate 106, a gate oxide layer 108 two source/drains' 110a and 110b. The NMOS capacitor 104 has a gate 112, a gate oxide layer 114 and two source/drains' 116a and 116b. The source/drain 110b of the NMOS transistor 102 and the gate 112 of the NMOS capacitor 104 are connected electrically through a via plug 118 and a metallic layer 120. The source/drain 116a and the source/drain 116b of the NMOS capacitor 104 as well as the substrate 100 are electrically connected to a ground.

FIG. 1B is an equivalent circuit diagram of a conventional semiconductor programmable device. As shown in FIGS. 1A and 1B, a control voltage V is applied to the gate 106 of the NMOS transistor 102. The control voltage V is the punch through voltage for the gate 112 of the NMOS capacitor 104. A programming voltage Vs is applied to the source/drain 110a of the NMOS transistor 102. Furthermore, the NMOS transistor 102 has a threshold voltage Vt. To punch through the NMOS capacitor 104, the control voltage V must be greater than the sum of the programming voltage Vs and the threshold voltage Vt. In other words, the NMOS transistor 102 conducts and punches through the gate oxide layer 114 of the NMOS capacitor 104 so that the gate 112 is shorted then connected with the ground equivalent to blowing a safety fuse.

Since the aforementioned semiconductor programmable device mainly comprises an NMOS transistor and an NMOS capacitor, the device occupies a volume roughly only 1/70^{th} of the earlier safety fuse. Furthermore, unlike a laser burnt safety fuse that may damage neighboring devices during repair, connection to the semiconductor device is achieved through electrical programming. Hence, repairing operation can be carried out even after the chip has already been packaged.

As shown in FIGS. 1A and 1B, a control voltage V greater than the sum of the programming voltage Vs and the threshold voltage Vt of the NMOS transistor 102 needs to be applied if a punch through of the NMOS capacitor 104 within the semiconductor programmable device is required. With the application of a relative high control voltage V, it is possible to cause a punch through of the gate oxide layer 106 of the NMOS transistor 102 leading to a short circuit failure of the entire device. To prevent a punch through by the control voltage V, the gate oxide layer 106 in the NMOS transistor 102 must have a thickness greater than the gate oxide layer 114 of the NMOS capacitor 104. However, producing the gate oxide layer 106 and the gate oxide layer 114 such that each has a different thickness requires a more complicated fabrication process and hence increases overall production cost.

Moreover, the application of a large control voltage V may cause some abnormality in the operation of field devices or a drop in overall device performance. In some cases, breakdown may occur at the junction between the N-type source/drain 110a or source/drain 110b of the NMOS transistor 102 and the P-type substrate 100. Ultimately, current may leak from the NMOS transistor 102.

### SUMMARY OF THE INVENTION

Accordingly, at least one objective of the present invention is to provide a semiconductor programmable device that can be activated using a lower control voltage to prevent a voltage breakdown.

A second objective of this invention is to provide a semiconductor programmable device with an identical transistor and capacitor gate oxide layer thickness so that the fabrication process can be simplified and the production cost can be reduced.

To achieve these and other advantages and in accordance with the purpose of the invention, as embodied and broadly described herein, the invention provides a semiconductor programmable device. The semiconductor programmable device comprises a P-type substrate, an N-well, an NMOS capacitor and a PMOS transistor. The N-well is formed in the P-type substrate. The NMOS capacitor is configured on the P-type substrate. The NMOS capacitor has at least a first gate. The PMOS transistor is configured on the N-well. The PMOS transistor has a second gate, a first source/drain and a second source/drain. The first source/drain of the PMOS transistor is connected electrically to the first gate of the NMOS capacitor. A control voltage is applied to the second gate of the PMOS transistor. A programming voltage is applied to the second source/drain of the PMOS transistor. The programming voltage is large enough to cause a punch through in the NMOS capacitor.

This invention also provides an alternative semiconductor programmable device. The semiconductor programmable device comprises a P-type substrate, an N-well, an NMOS capacitor and a PMOS transistor. The N-well is formed in the P-type substrate. The NMOS capacitor is configured on the P-type substrate. The NMOS capacitor has at least a first gate. A first gate oxide layer is formed between the first gate and the P-type substrate. The PMOS transistor is configured on the N-well. The PMOS transistor has a second gate, a first source/drain and a second source/drain. A second gate oxide layer is formed between the second gate and the N-well. The first source/drain of the PMOS transistor is connected electrically to the first gate of the NMOS capacitor. A control voltage is applied to the second gate of the PMOS transistor. A programming voltage is applied to the second source/drain of the PMOS transistor. The programming voltage is large enough to punch through the second gate oxide layer of the NMOS capacitor. The first gate oxide layer of the NMOS capacitor has a thickness identical to the second gate oxide layer of the PMOS transistor.

In this invention, a PMOS transistor is used instead of the conventional NMOS transistor to prevent possible unexpected operations in other devices on the chip when too large a control voltage is applied as well as voltage breakdown. Furthermore, because both the transistor and the capacitor gate oxide layer has an identical thickness, the process of fabricating the semiconductor programmable device is simplified so that overall production cost is reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a conventional semiconductor programmable device.

FIG. 1B is an equivalent circuit diagram of a conventional semiconductor programmable device.

FIG. 2 is a schematic cross-sectional view of a semiconductor programmable device according to one preferred embodiment of this invention.

FIG. 3 is an equivalent circuit diagram of a semiconductor programmable device according to one preferred embodiment of this invention.

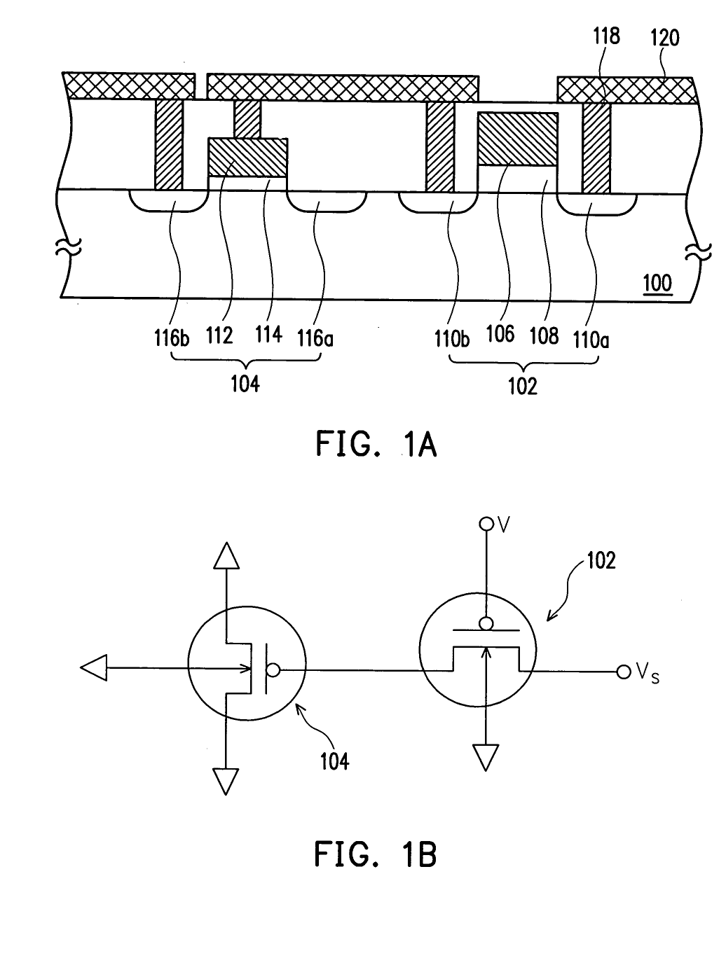

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

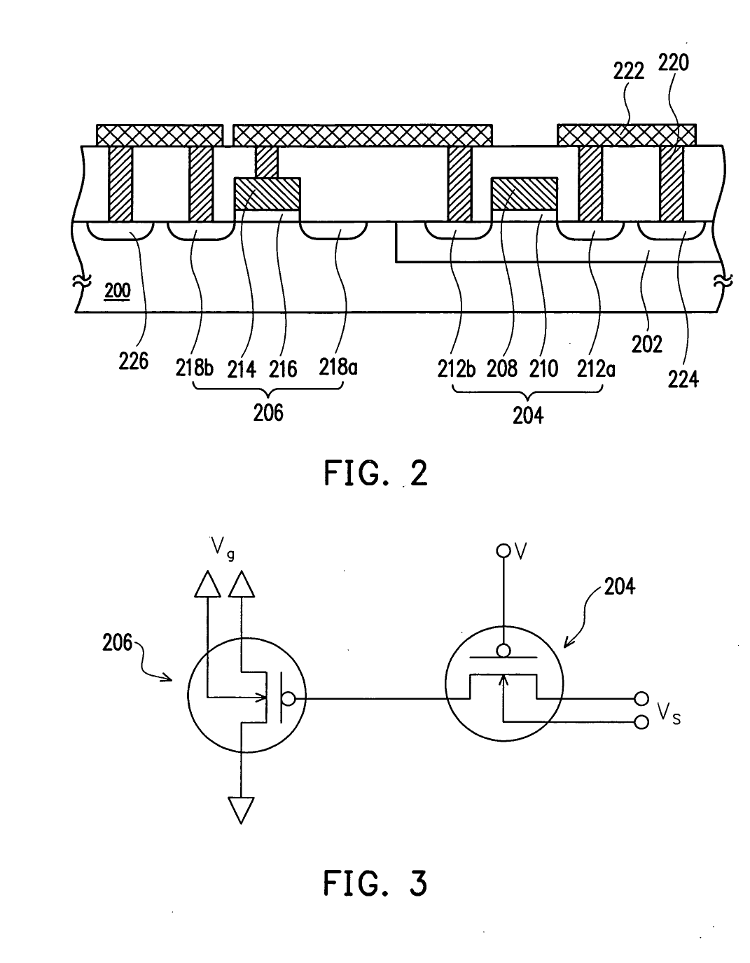

FIG. 2 is a schematic cross-sectional view of a semiconductor programmable device according to one preferred embodiment of this invention. As shown in FIG. 2, the semiconductor programmable device comprises a P-type substrate 200, an N-well 202, a PMOS transistor 204 and an NMOS capacitor 206. The P-type substrate 200 is a silicon substrate with lightly doped P-type dopants, for example. The N-well 202 is configured within the P-type substrate 200. The N-well 202 is formed, for example, by lightly doping N-type dopants into the P-type substrate in an ion implantation.

The PMOS transistor 204 has a gate 208, a gate oxide layer 210 and two source/drains' 212a and 212b. The gate oxide layer 210 and the gate 208 are sequentially set over the N-well 202. The source/drain 212a and the other source/drain 212b are formed within the N-well 202, for example, by heavily doping P-type dopants into the N-well 202 in an ion implantation.

The NMOS capacitor 206 has a gate 214, a gate oxide layer 216 and source/drains' 218a and 218b. The gate oxide layer 216 and the gate 214 are sequentially set over the P-type substrate 200. The source/drains' 218a and 218b are formed within the P-type substrate 200, for example, by heavily doping N-type dopants into the P-type substrate 200 in an ion implantation.

The source/drain 212b of the PMOS transistor 204 is electrically connected to the gate 214 of the NMOS capacitor 206 through a via plug 220 and a metallic layer 222 so that the PMOS transistor 204 and the NMOS capacitor 206 are serially connected together. Furthermore, the source/drain 212a of the PMOS transistor 204 is also electrically connected to the heavily doped N-type region 224 within the N-well 202 through the via plug 220 and the metallic layer 222. Hence, the N-well 202 and the source/drain 212a are at the same potential during operation.

For the NMOS capacitor 206, the source/drain 218b is electrically connected to the heavily doped P-type region 226 within the P-type substrate 200 through the via plug 220 and the metallic layer 222. Therefore, the P-type substrate 200 and the source/drain 218b are at the same potential during operation. The P-type substrate 200, the source/drain 218a and the source/drain 218b are connected to a ground.

The via plug 220 and the metallic layer 222 are formed by performing a metallic interconnect process. Since the process for forming metallic interconnects is known to anyone familiar with the technology, detailed description is omitted herein.

FIG. 3 is an equivalent circuit diagram of a semiconductor programmable device according to one preferred embodiment of this invention. As shown in FIGS. 2 and 3, a control voltage V is applied to the gate 208 of the PMOS transistor 204. The control voltage V serves as a punch through voltage for the gate 214 of the NMOS capacitor 206. A programming voltage Vs is applied to the source/drain 212a of the NMOS capacitor 206. Because the source/drain 212a is electrically connected to the heavily doped N-type region 224 within the N-well 202, the N-well 202 is at the same potential as the programming voltage Vs. The source/drain 218a and the source/drain 218b of the NMOS capacitor 206 as well as the P-type substrate 200 are connected to a ground voltage Vg, for example, a 0V.

To operate the device, the NMOS capacitor 206 is programmed (by punching through the gate oxide layer 216) to form a short circuit. Because the PMOS transistor 204 has a threshold operating voltage Vt, the control voltage V must be smaller than the difference between the programming voltage Vs and the threshold voltage Vt but greater than the ground voltage Vg. Thus, the PMOS transistor 204 conducts and punches through the gate oxide layer 216 of the NMOS capacitor 206 to form a short circuit in the gate 214.

This invention replaces the conventional NMOS transistor with a PMOS transistor. Hence, an N-well is needed within the P-type substrate. Furthermore, the electric potential at the N-well is identical to the programming voltage Vs applied to the source/drain of the PMOS transistor. Therefore, the electrical breakdown at the junction boundary between the source/drain and the N-well is prevented.

Furthermore, the control voltage V required to activate the semiconductor programmable device of this invention is much smaller than a conventional device. In other words, unexpected actions in other devices on the chip due to a high control voltage input is minimized and the probability of having a punch through of the gate oxide layer is reduced.

In addition, the concentration of dopants within the N-well and the P-type substrate are almost identical so that their junction boundary has a large breakdown voltage. Therefore, a leakage current resulting from a junction breakdown rarely occurs.

It is to be noted that the problem caused by punching through the gate of a MOS transistor during operation rarely occurs in the semiconductor programmable device of this invention because a low control voltage is used. Since there is no need to thicken the gate oxide layer of the transistor to prevent punch through, thickness of the gate oxide layer within the transistor and the capacitor can be identical. In other words, the fabrication process in this invention can be simplified to reduce production cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor programmable device, comprising:
a P-type substrate;
an N-well, set within the P-type substrate;
an NMOS capacitor, set on the P-type substrate, wherein the NMOS capacitor comprises at least a first gate; and
a PMOS transistor, set on the N-well, wherein the PMOS transistor comprises a second gate, a first source/drain and a second source/drain such that the first source/drain is electrically connected to the first gate of the NMOS capacitor, a control voltage is applied to the second gate and a programming voltage capable of punching through the NMOS transistor is applied to the second source/drain.

2. The semiconductor programmable device of claim 1, wherein the P-type substrate is electrically connected to a ground potential.

3. The semiconductor programmable device of claim 1, wherein the N-well is electrically connected to the programmable voltage.

4. The semiconductor programmable device of claim 1, wherein the PMOS transistor has an operating threshold voltage such that a control voltage smaller than the difference between the programming voltage and the threshold voltage but greater than the ground potential is required to punch through the NMOS capacitor.

5. A semiconductor programmable device, comprising:
a P-type substrate;
an N-well, set on the P-type substrate;
an NMOS capacitor, set on the P-type substrate, wherein the NMOS capacitor comprises at least a first gate and a first gate oxide layer is set between the first gate and the P-type substrate; and
a PMOS transistor, set on the N-well, wherein the PMOS transistor comprises a second gate, a first source/drain and a second source/drain such that a second gate oxide layer is set between the second gate and the N-well, the first source/drain is electrically connected to the first gate of the NMOS capacitor, a control voltage is applied to the second gate and a programming voltage capable of punching through the second gate oxide layer in the NMOS transistor is applied to the second source/drain and that the first gate oxide layer has a thickness identical to the second gate oxide layer.

6. The semiconductor programmable device of claim 5, wherein the P-type substrate is electrically connected to a ground potential.

7. The semiconductor programmable device of claim 5, wherein the N-well is electrically connected to the programmable voltage.

8. The semiconductor programmable device of claim 5, wherein the PMOS transistor has an operating threshold voltage such that a control voltage smaller than the difference between the programming voltage and the threshold voltage but greater than the ground potential is required to punch through the NMOS capacitor.
